(19) United States
(12) Patent Application Publication
(10) Pub. No.: US 2005/0120960 A1
(43) Pub. Date: Jun. 9, 2005

(54) Substrate holder for plasma processing

(75) Inventor: Lee Chen, Austin, TX (US)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 10/506,237

(22) PCT Filed: Mar. 11, 2003
(86) PCT No.: PCT/US03/06154

Related U.S. Application Data
(60) Provisional application No. 60/363,284, filed on Mar. 12, 2002.

(51) Int. Cl. C23C 16/00

(52) U.S. Cl. 118/728

(57) ABSTRACT

An improved substrate holder comprises an electrode supporting a focus ring and a substrate, an insulating member surrounding the electrode and focus ring, a ground member surrounding the insulating member, and a focus ring surrounding the substrate. The focus ring provides a RF impedance substantially equivalent to a RF impedance of the substrate. A method of processing a substrate utilizing the improved substrate holder reduces arcing between the edge of the substrate and the focus ring. The method comprises the steps of placing the focus ring on the electrode, placing the substrate on the electrode and processing the substrate. Additionally, a method of controlling a focus ring temperature and a substrate temperature utilizing the improved substrate holder comprises the steps of placing the focus ring on the electrode, placing the substrate on the electrode, clamping the focus ring and the substrate to the electrode using an electrostatic clamp, supplying heat transfer gas(es) to the space residing between the focus ring and the electrode, and the space between the substrate and the electrode, and controlling the temperature of the electrode.

### CROSS-REFERENCE TO RELATED APPLICATIONS

The present application claims priority and is related to U.S. application No. 60/363,284, filed on Mar. 12, 2002, the entire contents of which are herein incorporated by reference in their entirety.

### BACKGROUND OF THE INVENTION

1. Field of Invention

The present invention relates to substrate holders employed in plasma processing and more particularly to an improved substrate holder for plasma processing.

2. Description of Related Art

One area of plasma processing in the semiconductor industry which presents formidable challenges is, for example, the manufacture of integrated circuits (ICs). Demands for increasing the speed of ICs in general, and memory devices in particular, force semiconductor manufacturers to make devices smaller and smaller on the wafer surface. And conversely, while shrinking device sizes on the substrate is incurred, the number of devices fabricated on a single substrate is dramatically increased with further expansion of the substrate diameter (or processing real estate) from 200 mm to 300 mm and greater. Both the reduction in feature size, which places greater emphasis on critical dimensions (CD), and the increase of substrate size lead to even greater requirements on plasma processing uniformity to maximize the yield of superior devices.

One such consequence of non-uniform plasma processing can be, for example, the unequal charging of the substrate surface in contact with the plasma and the focus ring surrounding the substrate. Using current focus ring design practice, the surface potential of the focus ring can be substantially different than the surface potential of the substrate. Subsequently, the difference in surface potential can lead to a non-uniform plasma sheath thickness and, therefore, result in non-uniform plasma properties proximate the substrate edge. Moreover, the difference in surface potential between the substrate edge and focus ring can be sufficiently great to cause an electrical discharge (arc) arising in a catastrophic process failure and reduced device yield.

In a known plasma processing system, substrate arcing has been observed and can be attributable to the aforementioned focus ring design. For example, FIG. 1 presents a known substrate holder 1 comprising a RF biasable electrode 10, electrode insulator 12, ground wall 14 with surface anodization 16, and focus ring 18. The substrate holder 1 further includes an electrostatic clamp (ESC) 20 in order to facilitate holding a substrate 22. Although, not shown in detail in FIG. 1, the electrostatic clamp 20 typically comprises a clamp electrode encased within a ceramic body. The focus ring 18 is generally fabricated from a silicon-containing material such as, for example, silicon or silicon carbide, when processing silicon substrates. However, the material and size of the focus ring 18 can result in a low capacitance or corresponding high RF impedance leading to a surface potential substantially greater than the surface potential of the substrate 22. As a consequence, the plasma sheath 30 can be substantially non-uniform, comprising a thin region 32 above the focus ring 18, a thicker region 34 above the substrate 22 and a transitional region 36 existing therebetween.

As stated above, the potential difference associated with the non-uniform plasma sheath can manifest as substrate arcing, hence, leading to catastrophic reduction in device yield. It is, therefore, desirable to achieve a uniform plasma sheath thickness across the substrate and the surfaces proximate the edge of the substrate.

An additional shortcoming of current focus ring design practice includes a substantially different temperature between the substrate and the focus ring. In fact, it is not unrealistic to observe focus ring temperatures exceeding the substrate temperature by more than several hundred degrees centigrade. This observation is primarily attributable to the poor thermal contact between the focus ring and the temperature controlled electrode. As a consequence, the “hot” focus ring can heat the substrate edge leading to non-uniform substrate temperatures and, hence, non-uniform substrate processing particularly local to the substrate edge. It is, therefore, desirable to control the focus ring temperature as well as the substrate temperature.

### SUMMARY OF THE INVENTION

The present invention provides for an improved substrate holder for a plasma processing system in order to alleviate the aforementioned shortcomings of known substrate holders. The improved substrate holder comprises an electrode supporting a focus ring and a substrate on an upper surface thereof, an insulating member surrounding the electrode and focus ring, a ground member surrounding the insulating member, and a focus ring surrounding the substrate. The focus ring comprises a RF impedance substantially equivalent to a RF impedance of the substrate.

It is a further object of the present invention to provide an improved substrate holder further comprising an electrostatic clamp, wherein the electrostatic clamp can serve as the upper surface of the electrode.

It is a further object of the present invention to provide an improved substrate holder further comprising a heating and cooling system for controlling the temperature of the electrode.

The present invention further describes a method of processing a substrate utilizing the improved substrate holder in order to minimize arcing between the edge of the substrate and the focus ring. The method comprises the steps of placing the focus ring on the electrode, placing the substrate on the electrode and processing the substrate.

Additionally, the present invention describes a method of controlling a focus ring temperature and a substrate temperature utilizing the improved substrate holder. The method comprises the steps of placing the focus ring on the electrode, placing the substrate on the electrode, clamping the focus ring and the substrate to the electrode using an electrostatic clamp, supplying heat transfer gas(es) to a first space residing between the focus ring and the electrode, and a second space residing between the substrate and the electrode, and controlling a temperature of the electrode.

### BRIEF DESCRIPTION OF THE DRAWINGS

These and other objects and advantages of the invention will become more apparent and more readily appreciated from the following detailed description of the exemplary embodiments of the invention taken in conjunction with the accompanying drawings, where:

FIG. 1 presents a schematic cross-section of a known substrate holder indicating a non-uniform plasma sheath;

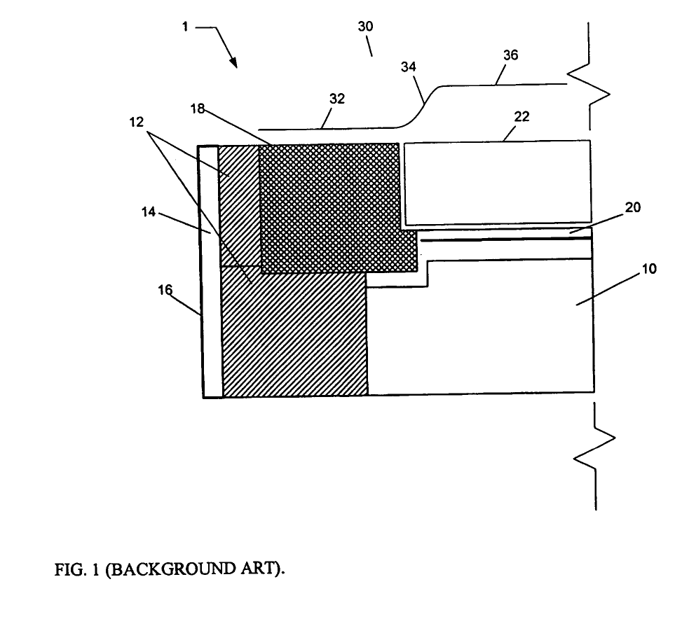

FIG. 2A presents a schematic cross-section of an improved substrate holder according to an embodiment of the present invention;

FIG. 2B presents a schematic cross-section of an improved substrate holder according to another embodiment of the present invention;

FIG. 2C presents a schematic cross-section of an improved substrate holder according to another embodiment of the present invention;

FIG. 3 presents a flow diagram for a method of minimizing arcing between a substrate and a focus ring according to a first embodiment of the present invention; and

FIG. 4 presents a flow diagram for a method of controlling substrate and focus ring temperature according to a second embodiment of the present invention.

### DETAILED DESCRIPTION OF EXEMPLARY EMBODIMENTS

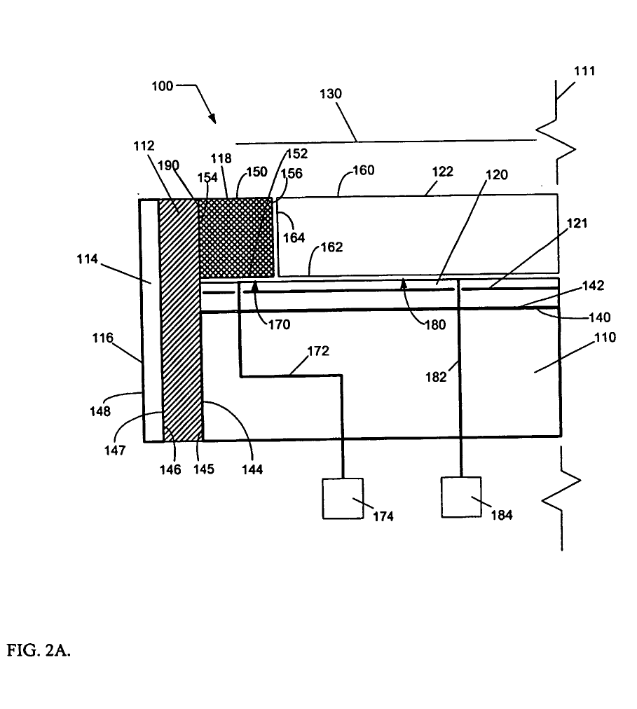

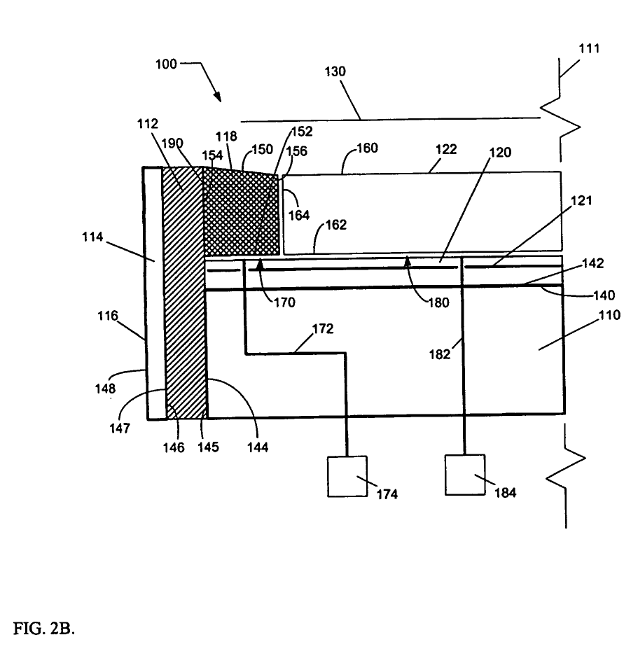

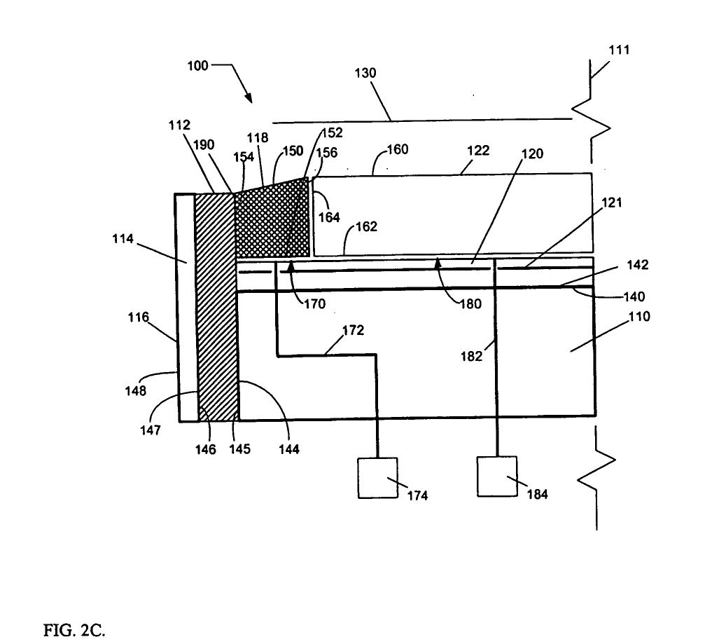

The present invention relates to a substrate holder employed in plasma processing and more particularly to an improved substrate holder for plasma processing. According to the illustrated embodiment of the present invention depicted in FIG. 2A, an improved substrate holder 100 can comprise an electrode 110, an insulating member 112 and a ground member 114. A focus ring 118, comprising an upper surface 150, a lower surface 152, an outer surface 154 at an outer diameter and an inner surface 156 at an inner diameter, is coupled to an upper surface 140 of electrode 110. The inner diameter of inner surface 156 of focus ring 118 is sufficiently large to accommodate substrate 122 and to center substrate 122 about an axis of revolution 111 of electrode 118. Substrate 122 comprises an upper surface 160, a bottom surface 162, and an outer surface 164 at an outer diameter facing inner surface 156 of focus ring 118. Substrate 122 is coupled to electrode 110 in such a way that bottom surface 162 of substrate 122 opposes upper surface 140 of electrode 110.

In order to preserve a uniform plasma sheath thickness 130 across both the upper surface 150 of focus ring 118 and the upper surface 160 of substrate 122 and, hence, a spatially homogeneous surface potential, focus ring 118 is designed and implemented as an electrical element comprising an RF impedance substantially similar to that of substrate 122. In a first embodiment, focus ring 118 comprises, for example, at least one of silicon and silicon carbide when processing a substrate 122 comprising, for example, silicon. The material properties of focus ring 118 are specifically chosen to produce a RF impedance for focus ring 118 that is substantially equivalent to the RF impedance of substrate 122. Focus ring 118 can comprise material properties such that its inherent capacitance, inductance and resistance are similar to that of substrate 122. For example, focus ring 118 can comprise heavily doped silicon carbide when processing a substrate 122 comprising silicon. In an alternate embodiment, the upper surface 150 of focus ring 118 can comprise a shape other than flat, such as, for example, an inclined surface as shown in FIGS. 2B and 2C. In an alternate embodiment (not shown), the upper surface 150 of focus ring 118 comprises at least one of a convex and a concave surface. Furthermore, the thickness of focus ring 118 is designed to be tailored to the thickness of substrate 122. The thickness of substrate 122 can be, for example, 750 micron. In one embodiment, the focus ring has a thickness of 100 to 2000 microns. In another embodiment, the focus ring has a thickness substantially equivalent to the thickness of the substrate 122. Exemplary thicknesses of the focus ring include, but are not limited to, (1) a thickness within 20% of the thickness of the substrate, (2) a thickness within 10% of the thickness of the substrate, (3) a thickness within 5% of the thickness of the substrate, and (4) a thickness within 1% of the thickness of the substrate. In an alternate embodiment, the thickness of focus ring 118 is substantially different than the thickness of substrate 122.

Electrode 110 can be, for example, generally cylindrical comprising an outer surface 144 at an outer diameter and an axis of rotation 111. Additionally, electrode 110 can comprise aluminum and, therefore, it can be anodized, hence, comprising an anodization layer 142, as depicted in FIG. 2A. Desirably, the outer diameter of outer surface 144 of electrode 110 is substantially equivalent to outer diameter of outer surface 154 of focus ring 118. In an alternate embodiment, the outer diameter of outer surface 144 of electrode 110 is different than the outer diameter of outer surface 154 of focus ring 118.

Insulating member 112, can also be, for example, generally cylindrical comprising an inner surface 145 at an inner diameter, an outer surface 146 at an outer diameter and an axis of revolution 111. Desirably, the inner surface 145 corresponds to an inner diameter substantially equivalent to the outer diameter of outer surface 144 of electrode 110. Moreover, the inner diameter of inner surface 145 of insulating member 112 can be substantially equivalent to the outer diameter of the outer surface 154 of focus ring 118. Therefore, insulating member 112 can comprise an inner edge 190 substantially flush with the outer surface 154 of focus ring 118 in order to serve as a means of centering focus ring 118 about axis of revolution 111. In an alternate embodiment, insulating member 112 can comprise an inner surface 145 having an inner diameter different than the outer diameter of outer surface 154 of focus ring 118 and, therefore, allow an edge (or groove) 190 to be machined within the upper surface of insulating member 112 in order to serve the centering function described above. Preferably, insulating member 112 comprises a dielectric material such as, for example, quartz or alumina.

Ground member 114 can also be, for example, generally cylindrical comprising an inner surface 147 at an inner diameter, an outer surface 148 at an outer diameter and an axis of revolution 111. Desirably, the inner surface 147 corresponds to an inner diameter substantially equivalent to the outer diameter of outer surface 146 of insulating member 112. Additionally, ground member 114 can comprise aluminum and, therefore, it can be anodized, hence, comprising an anodization layer 116, as depicted in FIG. 2A.

Alternately, the substrate 122 can be, for example, affixed to the substrate holder 100 via an electrostatic clamp 120. Electrostatic clamp 120 comprises a clamp electrode 121 connected to a high voltage (HV), direct current (DC) voltage source (not shown). Typically, the clamp electrode is fabricated from copper and embedded within a ceramic element. The electrostatic clamp 120 can be operable in either a monopolar or bipolar mode; each mode is well known to those skilled in the art of electrostatic clamping systems. Desirably, clamp electrode 120 can serve as upper surface 140 of electrode 110 and extends under the lower surface 152 of focus ring 118 and the lower surface 162 of substrate 122. In one embodiment, electrostatic clamp 120 can be utilized to clamp both the focus ring 118 and the substrate 122. In another embodiment, electrostatic clamp 120 can comprise two or more independent clamp electrodes with separate HV DC voltage sources for independently clamping the focus ring 118 and the substrate 122.

Alternately, electrode 110 can further include a cooling/heating system including a re-circulating fluid that receives heat from substrate 122 and focus ring 118 and transfers heat to a heat exchanger system (not shown) when cooling, or when heating, transfers heat from the heat exchanger system to the above elements. In other embodiments, heating elements, such as resistive heating elements, or thermoelectric heaters/coolers can be included as part of the heating/cooling system. The heating/cooling system further comprises a device (not shown) for monitoring the electrode 110 temperature. The device can be, for example, a thermocouple (e.g., K-type thermocouple).

Moreover, heat transfer gas can be delivered to at least one of a first space 170 between upper surface 140 of electrode 110 and lower surface 152 of focus ring 118 using a first gas supply line 172, and a second space 180 between upper surface 140 of electrode 110 and lower surface 162 of substrate 122 using a second gas supply line 182 (see FIG. 2A). Gas supply lines 172 and 182 can distribute heat transfer gas to one or more orifices or a groove formed in the upper surface 140 of electrode 110. The implementation of heat transfer gas distribution is well known to those skilled in the art of substrate processing. The supply of heat transfer gas to the first space 170 can improve the gas-gap thermal conductance between the lower surface 152 of focus ring 118 and the upper surface 140 of electrode 110, while the supply of heat transfer gas to the second space 180 can improve the gas-gap thermal conductance between the lower surface 162 of substrate 122 and the upper surface 140 of electrode 120. The heat transfer gas can be, for example, at least one of a Noble gas such as helium, argon, neon, xenon, krypton, a process gas such as C₄F₈, CF₄, C₅F₈, C₄F₆ and C₂F₆, or a mixture thereof. Therefore, controlling the temperature of electrode 110 via the aforementioned heating/cooling system can lead to control of both the temperature of the focus ring 118 and the temperature of the substrate 122. In one embodiment, the supply of heat transfer gas to the first space 170 is independent of the supply of heat transfer gas to the second space 180 using independent gas supplies 174 and 184 as shown in FIG. 2A. Using independent heat transfer gas supplies, the pressure in first space 170 can be adjusted to be different than the pressure in second space 180. In an alternate embodiment, gas supply lines 172 and 182 are supplied heat transfer gas from a single heat transfer gas supply. In an alternate embodiment, the second space 180 is divided into one or more spaces to which heat transfer gas is supplied independently.

Substrate 122 can be, for example, transferred into and out of a process chamber (not shown) through a slot valve (not shown) and chamber feed-through (not shown) via robotic substrate transfer system where it is received by substrate lift pins (not shown) housed within substrate holder 100 and mechanically translated by devices housed therein. Therefore, lift pin holes (not shown) in electrode 110 and electrostatic clamp 120 accommodate the passage of lift pins to and from the lower surface 162 of substrate 122. Once substrate 122 is received from the substrate transfer system, it is lowered to an upper surface 140 of substrate holder 100.

In the illustrated embodiment, shown in FIG. 2A, electrode 110 can, for example, further serve as a RF electrode through which RF power is coupled to plasma in a processing region adjacent substrate 122. For example, electrode 110 is electrically biased at a RF voltage via the transmission of RF power from a RF generator (not shown) through an impedance match network (not shown) to electrode 110. The RF bias can serve to heat electrons and, thereby, form and maintain plasma or to provide a RF bias in order to enable control of ion energy at the upper surface 160 of substrate 122. In this configuration, the system can operate as a reactive ion etch (RIE) reactor, wherein the chamber serves as ground surfaces. A typical frequency for the RF bias can range from 1 MHz to 100 MHz and is preferably 13.56 MHz. RF systems for plasma processing are well known to those skilled in the art. Impedance match network topologies (e.g. L-type, π-type, T-type, etc.) and automatic control methods are also well known to those skilled in the art.

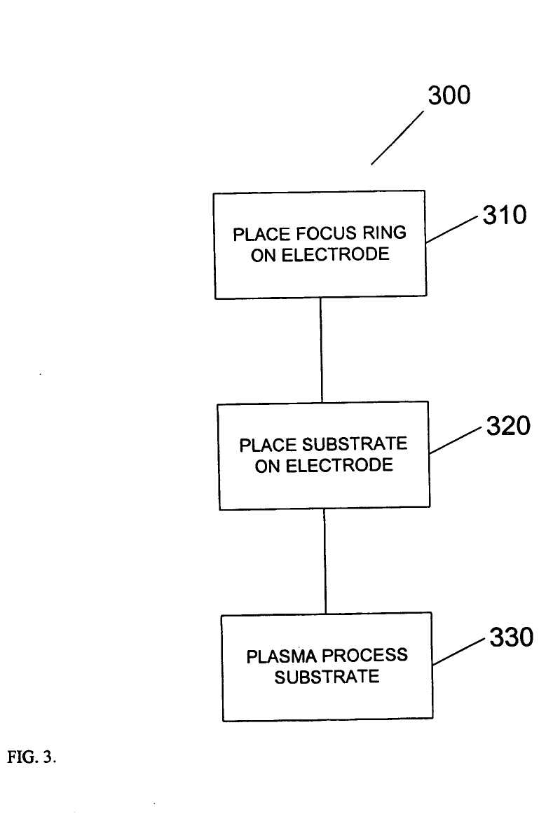

Referring now to FIG. 3, a flowchart 300 describes a method of processing a substrate using the improved substrate holder depicted in FIG. 2 in order to minimize the possibility of arcing between the substrate edge and the focus ring. The method begins with step 310 wherein a focus ring 118 as described above is placed upon substrate holder 100 and coupled to the upper surface 140 of electrode 110. The focus ring 118 can, for example, be set atop the electrode 110 by an operator during chamber maintenance. Furthermore, the focus ring 118 can be centered about an axis of revolution 111 by aligning the outer surface 154 of focus ring 118 flush with the inner edge 190 of insulating member 112. Alternately, focus ring 118 can be received and lowered to the upper surface 140 of electrode 110 by a set of lift pins (not shown), wherein the focus ring 118 is transferred into and out of the chamber via the robotic substrate transfer system described above.

In step 320, substrate 122 is placed upon substrate holder 100 and coupled to the upper surface 140 of electrode 110. The substrate 122 can, for example, be received and lowered to the electrode 110 by a set of lift pins (not shown), as described above, wherein substrate 122 is transferred into and out of the chamber via the robotic substrate transfer system. Furthermore, substrate 122 can be centered about an axis of revolution 111 by aligning the outer surface 164 of substrate 122 flush with the inner edge 156 of focus ring 118.

In step 330, substrate 122 is processed in the plasma processing system according to a process recipe. The process recipe can, for example, include setting the electrostatic clamping voltage (force), backside gas pressure (e.g. gas pressure in spaces 170 and 180), RF power to electrode 110, chamber gas pressure, process gas partial pressure(s) and flow rate(s), etc.

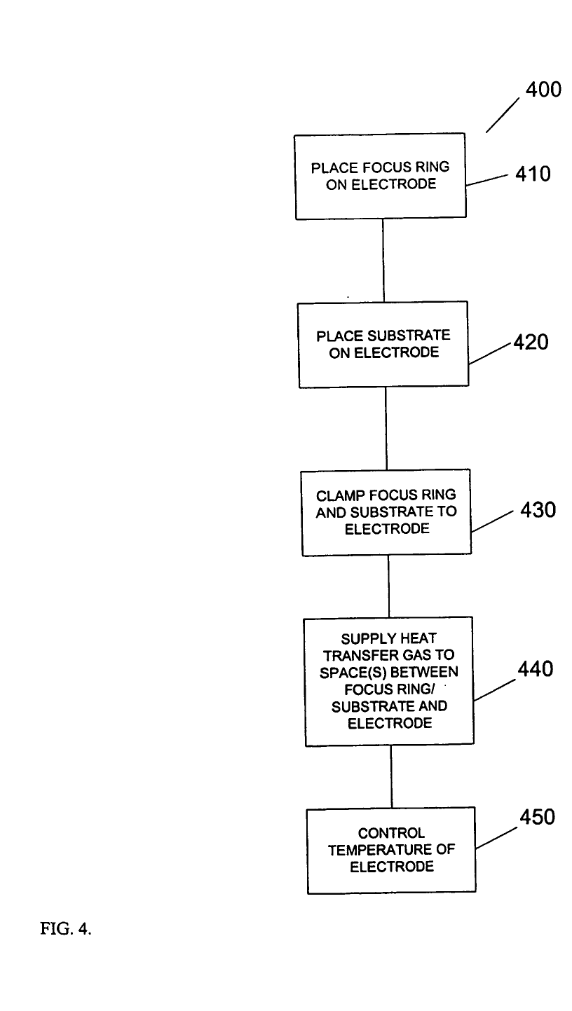

Referring now to FIG. 4, a flowchart 400 describes a method of processing a substrate using the improved substrate holder depicted in FIG. 2 in order to control the temperatures of focus ring 118 and substrate 122. The method begins with step 410 wherein, as before, a focus ring 118 as described above is placed upon substrate holder 100 and coupled to the upper surface 140 of electrode 110. The focus ring 118 can, for example, be set atop the electrode 110 by an operator during chamber maintenance. Furthermore, the focus ring 118 can be centered about an axis of revolution 111 by aligning the outer surface 154 of focus ring 118 flush with the inner edge 190 of insulating member 112. Alternately, focus ring 118 can be received and lowered to the upper surface 140 of electrode 110 by a set of lift pins (not shown), wherein the focus ring 118 is transferred into and out of the chamber via the robotic substrate transfer system described above.

In step 420, substrate 122 is placed upon substrate holder 100 and coupled to the upper surface 140 of electrode 110. The substrate 122 can, for example, be received and lowered to the electrode 110 by a set of lift pins (not shown), as described above, wherein substrate 122 is transferred into and out of the chamber via the robotic substrate transfer system. Furthermore, substrate 122 can be centered about an axis of revolution 111 by aligning the outer surface 164 of substrate 122 flush with the inner edge 156 of focus ring 118.

In step 430, a voltage supplied from a HV, DC voltage source is applied to electrostatic clamp 120 in order to provide a clamping force between the focus ring 118 and electrode 110 as well as the substrate 122 and electrode 110. In step 440, once the focus ring 118 and substrate 122 are clamped, a heat transfer gas can be supplied to the first and second spaces 170, 180 described above in order to improve the gas-gap thermal conductance between the focus ring 118 and electrode 110, and the substrate 122 and the electrode 110. In an embodiment of the present invention, the gas pressure in first space 170 is substantially equivalent to the gas pressure in second space 180. In an alternate embodiment, the gas pressure in first space 170 is substantially different than the gas pressure in second space 180.

In step 450, the temperature of electrode 110 is controlled via the heating/cooling system described above, thereby providing temperature control for the focus ring 118 and the substrate 122.

Although only certain exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

1. An improved substrate holder for plasma processing, the improvement comprising:
a focus ring, said focus ring surrounding a substrate wherein a thickness of said focus ring is substantially equivalent to a thickness of said substrate;
an electrode, said electrode is capable of supporting said substrate and said focus ring on an upper surface thereof;
an insulating member, said insulating member surrounding said electrode; and
a ground member, said ground member surrounding said insulating member.

2. The improvement according to claim 1, wherein said upper surface of said electrode further comprises at least one electrostatic clamp for clamping at least one of said focus ring and said substrate to said electrode, said at least one electrostatic clamp comprises a clamp electrode embedded within a ceramic member near said upper surface of said electrode, said clamp electrode extending below at least one of said focus ring and said substrate.

3. The improvement according to claim 1, wherein said insulating member is further capable of centering said focus ring.

4. The improvement according to claim 1, wherein said electrode is RF biasable.

5. The improvement according to claim 1, wherein said electrode is temperature controllable.

6. The improvement according to claim 2, wherein a space extending between said focus ring and said substrate, and said electrostatic clamp is supplied with a heat transfer gas.

7. The improvement according to claim 6, wherein said heat transfer gas comprises at least one of helium, argon, neon, xenon, krypton, C₄F₈, CF₄, C₅F₈, and C₂F₆.

8. The improvement according to claim 1, wherein said substrate comprises a silicon wafer.

9. The improvement according to claim 1, wherein said focus ring comprises at least one of silicon and silicon carbide.

10. The improvement according to claim 1, wherein said insulating member comprises at least one of quartz and alumina.

11. The improvement according to claim 1, wherein said ground member comprises at least one of anodized aluminum and aluminum.

12. The improvement according to claim 1, wherein said thickness of said focus ring ranges from 100 micron to 2000 micron.

13. The improvement according to claim 1, wherein said thickness of said focus ring is within 20% of said thickness of said substrate.

14. The improvement according to claim 1, wherein said thickness of said focus ring is within 10% of said thickness of said substrate.

15. The improvement according to claim 1, wherein said thickness of said focus ring is within 5% of said thickness of said substrate.

16. The improvement according to claim 1, wherein said thickness of said focus ring is within 1% of said thickness of said substrate.

17. An improved substrate holder for plasma processing, the improvement comprising:
a focus ring, said focus ring surrounding a substrate wherein a RF impedance of said focus ring is substantially equivalent to a RF impedance of said substrate;
an electrode, said electrode is capable of supporting said substrate and said focus ring on an upper surface thereof;
an insulating member, said insulating member surrounding said electrode; and
a ground member, said ground member surrounding said insulating member.

18. A method of minimizing arcing between a substrate and a focus ring during plasma processing, the method comprising the steps of:
placing a focus ring on an electrode, said focus ring centered about an axis of revolution of said electrode by an insulating member, said insulating member surrounding said electrode;
placing a substrate on an electrode, said substrate centered about said axis of revolution of said electrode by said focus ring; and
plasma processing said substrate utilizing a process recipe.

19. A method of controlling a temperature of a substrate and a focus ring, the method comprising the steps of:
placing a focus ring on an electrode, said focus ring centered about an axis of revolution of said electrode by an insulating member, said insulating member surrounding said electrode;
placing a substrate on an electrode, said substrate centered about said axis of revolution of said electrode by said focus ring;
clamping at least one of said focus ring and said substrate to said electrode using an electrostatic clamp, wherein said electrostatic clamp is fabricated within an upper surface of said electrode;
supplying a heat transfer gas to a first space between said focus ring and said electrode, and a second space between said substrate and said electrode; and
controlling the temperature of said electrode.

20. The method as claimed in claim 19, wherein the step of clamping comprises clamping said focus ring and said substrate to said electrode using the same electrostatic clamp.

21. The method as claimed in claim 19, wherein the step of clamping comprises clamping said focus ring and said substrate to said electrode using different electrostatic clamps.
